(19) United States
(12) Patent Application Publication
(10) Pub. No.: US 2012/0289043 A1
(43) Pub. Date: Nov. 15, 2012

(54) METHOD FOR FORMING DAMASCENE TRENCH STRUCTURE AND APPLICATIONS THEREOF

(75) Inventors: Ming-Da HSIEH, Kaohsiung City (TW); Yu-Tsung Lai, Fengyuan City (TW); Jiunn-Hsiung Liao, Shanhua Township (TW)

(73) Assignee: UNITED MICROELECTRONICS CORP., HSINCHU (TW)

(21) Appl. No.: 13/105,987

(22) Filed: May 12, 2011

(51) Int. Cl. H01L 21/768

(52) U.S. Cl. 438/643; 438/653; 257/E21.584

(57) ABSTRACT

A method for fabricating a damascene trench structure, wherein the method comprises steps as follows: A semiconductor structure having an inner layer dielectric (ILD) and a patterned hard mask stacked in sequence is firstly provided, in which a trench extends from the patterned hard mask downwards into the ILD. Subsequently, the patterned hard mask is etched in an atmosphere essentially consisting of nitrogen (N₂) and carbon-fluoride compositions (CₓF_{y}).

### FIELD OF THE INVENTION

The present invention relates to a method for fabricating a semiconductor device, more particularly to the method for forming a damascene trench structure and the applications thereof.

### BACKGROUND OF THE INVENTION

As integrated circuits become complex and the feature sizes continue to shrink, it becomes increasingly difficult to form interconnection patterns exhibiting the requisite circuit speed with high dimensional accuracy and reliability. Interconnection technology is constantly challenged to satisfy the ever-increasing requirements for high density and performance associated with ultra large scale integration semiconductor devices.

Instead of applying metal etching and dielectric gap filling processes to form an interconnection structure, like what the conventional multilevel interconnection technology did, a damascene interconnect technology simplify adopts an dielectric etching process and a metal deposition process to form the interconnection structure identical to what the conventional multilevel interconnection technology formed. In other words, to adopt the damascene interconnect technology for fabricating an interconnection structure, the conventional metal etching process which includes more production complexity is not necessary any more. The manufacturers may benefit from the damascene interconnect technology more, especially, as the interconnection structure is made of copper (Cu) rather tan aluminum (Al), hence an etching process conducted on a copper layer is more complex than that conducted on an aluminum layer. Accordingly, the damascene interconnect technology is of critical importance in fabricating a copper interconnection structure.

However, the damascene interconnect technology still has some drawbacks, for example, capper seed of the dielectric gap filling process may deposit overhead around the opening of the trenches or vias, so as to adversely affect the gap filling quality and device yield.

Therefore, it is necessary to provide an improved method for fabricating damascene trench structure and the applications thereof to obviate the drawbacks and problems encountered from the prior art.

### SUMMARY OF THE INVENTION

One aspect of the present invention is to provide a method for forming a damascene trench structure, wherein the method comprises steps as follows: A semiconductor structure having an inner layer dielectric (ILD) and a patterned hard mask stacked in sequence is firstly provided, in which a trench extends from the patterned hard mask downwards into the ILD. Subsequently, the patterned hard mask is etched in an atmosphere essentially consisting of nitrogen (N₂) and carbon-fluoride compositions (CₓF_{y}).

In one embodiment of the present invention, the atmosphere is a non-oxygen (O₂) atmosphere or a non-argon (Ar) atmosphere. In one embodiment of the present invention, the atmosphere essentially consists of nitrogen (N₂) and carbonteraflouride (CF₄). In one embodiment of the present invention, the atmosphere further comprises helium (He).

In another embodiment of the present invention, the step for providing the semiconductor structure further comprises following procedures: A substrate is first provide; a conducted layer is then formed on the substrate; a bottom layer is formed on the conductive layer; the ILD is formed on the bottom layer; a buffer layer is formed on the ILD; and the patterned hard mask is formed on the buffer layer, wherein the patterned hard mask has a trench opening exposing a portion of the buffer layer.

In one embodiment of the present invention, the step for providing the semiconductor structure further comprises: forming a photo-resist layer on the patterned hard mask so as to fill the trench opening; patterning the photo-resist layer to form a via opening aligning to the trench opening and exposing a portion of the buffer layer; conducting a via etching process using the patterned photo-resist layer serves as an etching mask to form a via exposing a portion of the bottom layer; and conducting a trench etching process using the patterned hard mask serves as an etching mask to form the trench passing through the bottom layer and exposing a portion of the conductive layer.

In one embodiment of the present invention, the photo-resist layer is a tri-layer photo-resist; and the photo-resist layer patterning comprises a pattern transferring procedure.

In one embodiment of the present invention, the formation of the patterned hard mask comprises steps of forming a titanium (Ti) layer on the buffer layer; forming a titanium nitride (TiN) layer on the Ti layer; and forming a capping layer on the TiN layer.

In one embodiment of the present invention, the trench etching process comprises: conducting a first etching step for removing a portion of the buffer layer; and conducting a second etching step for removing a portion of the ILD and exposing the conductive layer.

Another aspect of the present invention is to provide a method for fabricating a damascene interconnect structure, wherein the method comprises steps as follows: A semiconductor structure having an inner layer dielectric (ILD) and a patterned hard mask stacked in sequence is firstly provided, in which a trench extends from the patterned hard mask downwards into the ILD. Subsequently, the patterned hard mask is etched in an atmosphere essentially consisting of N₂ and CₓF_{y}. A metal material is then filled into the trench in connection with the conductive layer exposed from the trench.

In one embodiment of the present invention, the metal material filling steps further comprises a seed deposition to form a metal seeding layer on the sidewalls of the trench.

In accordance with the aforementioned embodiments of the present invention, a method for forming a damascene trench structure in a semiconductor structure is provided, wherein the semiconductor structure comprises an ILD and a patterned hard mask stack in sequence. After a trench extending from the patterned hard mask downwards into the ILD is formed in the semiconductor structure, an etching process having an etching atmosphere essentially consisting of N₂ and CₓF_{y} is conducted to pull back the patterned hard mask disposed on the trench. Thereby, the width of the trench opening can be enlarged so as to enable the subsequent dielectric gap filling process be conducted successfully. Therefore, the drawbacks and problems encountered from the prior art can be solved.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1E illustrate cross sectional views of a series processing structures for fabricating a single damascene interconnect structure in accordance with one embodiment of the present invention.

FIGS. 2A to 2H illustrate cross sectional views of a series processing structures for fabricating a single damascene interconnect structure in accordance with one embodiment of the present invention.

### DETAILED DESCRIPTION OF PREFERRED EMBODIMENTS

The objects of the present invention are to provide a method for forming a damascene trench structure and the applications thereof. The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

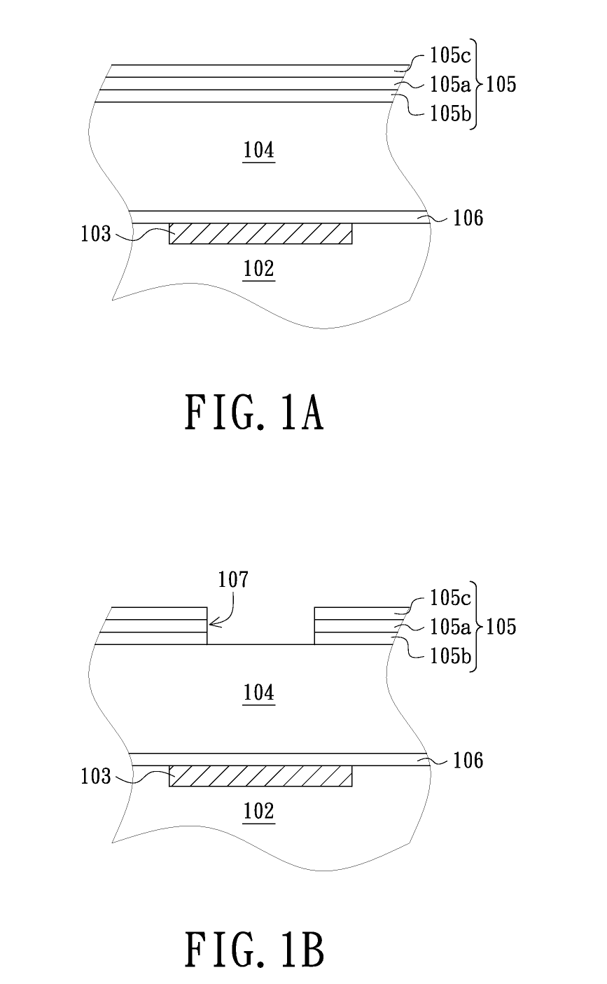

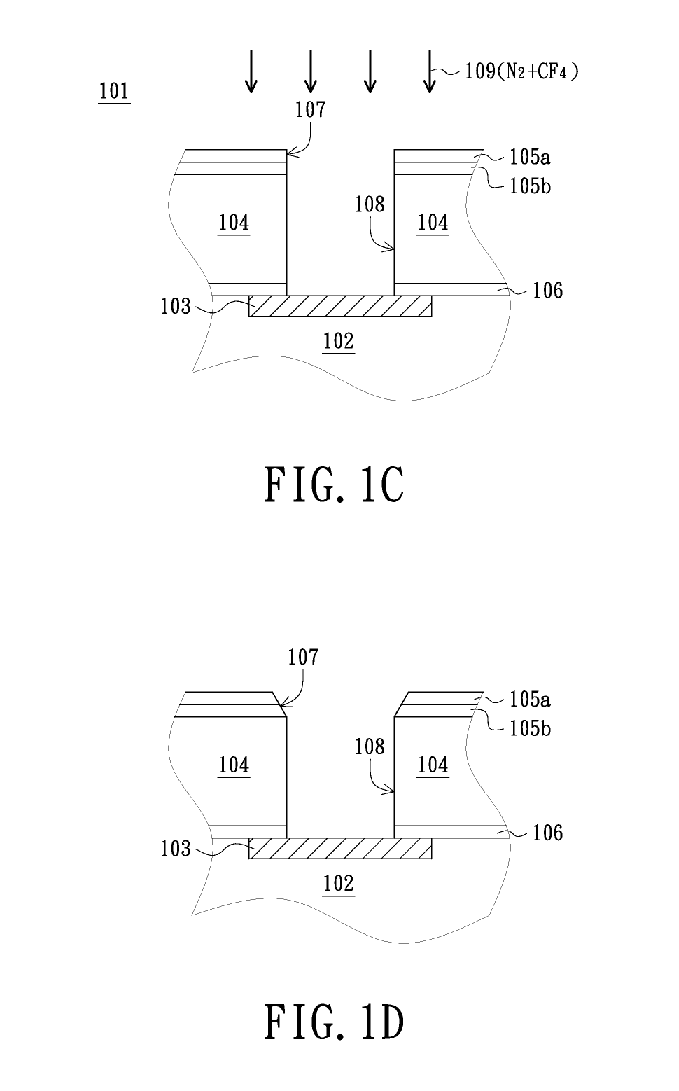

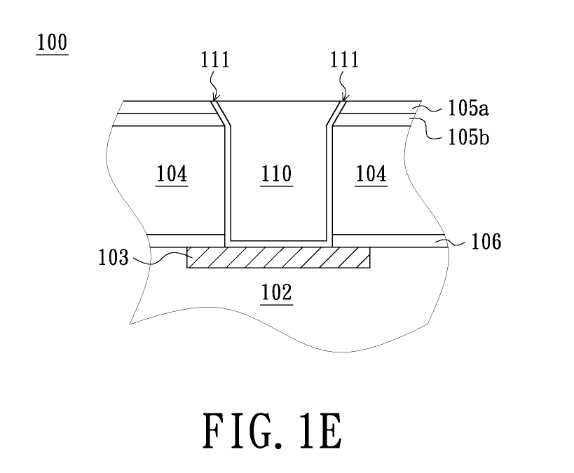

FIGS. 1A to 1E illustrate cross sectional views of a series processing structures for fabricating a single damascene interconnect structure 100 in accordance with one embodiment of the present invention. The method for fabricating the single damascene interconnect structure 100 comprises steps as follows:

A substrate 102 shown as the FIG. 1A is first provided, and then a conductive layer 103, an ILD 104 and a hard mask layer 105 are formed in sequence over the substrate 102. Wherein the substrate 102 preferably is a silicon substrate; the conductive layer 103 may be a metal layer; the ILD 104 is preferably made of low resistance materials (k≦2.9), such as fluorinated silicate glass (FSG), organosilicate glass (OSG) or other ultralow-k (ULK) materials; and the hard mask layer 105 comprises a TiN layer 105a, a Ti layer 105b disposed beneath the TiN layer 105a and an silicon oxide capping layer 105c disposed on the TiN layer 105a. In some preferred embodiments, there is a bottom layer 106 consisting of silicon nitride (SiN) or silicon carbon nitride (SiCN) formed between the conductive layer 103 and the ILD 104.

Next, the hard mask layer 105 is patterned to form at least one trench opening 107 exposing a portion of the ILD 104. Subsequently, a trench etching process is conducted using the patterned hard mask layer 105 serves as an etching mask to form a trench 108. As shown in FIG. 1C, the trench 108 formed in the semiconductor structure 101 extends from the patterned hard mask layer 105 and passing through the ILD 104 and the bottom layer 106, whereby a portion of the conductive layer 103 is exposed. In the embodiments of the present invention, the trench etching process preferably is a plasma-based dry etching process which can also remove the silicon oxide capping layer 105c.

However, it should be appreciated that the bottom layer 106 may not be etched through by the trench etching process. Rather, in some embodiments of the present invention, the bottom layer 106 may be etched through by a subsequent etching process 109, thus the conductive layer 103 is exposed from the trench 108 after the etching process 109 is conducted. In the embodiments of the present invention, the etching process 109 is a dry etching process having an etching atmosphere essentially consisting of N₂ and CₓF_{y} used to remove a portion of the patterned hard mask 105 disposed over the sidewalls of the trench 108, and enlarge the width of the trench opening 107.

Typically, the aforementioned trench etching process may generate carbon-fluoride polymer residue remaining on the surface of the patterned hard mask 105 and the sidewalls of the trench 108, which may obstruct the subsequent process. The N₂ gas of the etching process 109 can react with and take away the carbon-fluoride polymer remained on the surface of the TiN layer 105a so as to enhance the etching process 109 pulling back the TiN layer 105a from the sidewalls of the trench 108 and to round the corner of the trench opening 107. Thereby, the portion of the patterned hard mask 105 disposed over the sidewalls of the trench 108 used to define the trench opening 107 may pull back, and the width of the trench opening 107 is enlarged (shown in FIG. 1D). In addition, the carbon-fluoride polymer may be removed more quickly, when the partial pressure of the N₂ atmosphere is increased; and the width of the trench opening 107 can be further enlarged if the thickness of the patterned hard mask 105 is shrinking. In the present embodiment, the etching process 109 is a plasma-based etching process with the atmosphere essentially consisting of N₂ and CF₄.

It should be noted that, although an etching process with O₂ atmosphere can also be used to remove the carbon-fluoride polymer, the etching process 109 is a non-O₂ atmosphere etching process. It is because that the etching process with O₂ atmosphere has a similar selectivity for removing the TiN layer 105a and the ILD 104, thus it is difficult to control the etching depth. Therefore, if the etching process 109 imposes O₂ gas, the conductive layer 103 may be damaged by the O₂ gas due to an over-etching.

Besides, in order to remove the carbon-fluoride polymer remained on the sidewalls of the trench 108; an inert gas, such as Ar gas, is typically introduced into the O₂ atmosphere during the etching process 109. However, the O₂ atmosphere mixed with Ar gas may cause a sidewall etching by which a portion of the ILD 104 exposed from the trench 108 can be removed, so as to make the trench 108 shapes as a bowling and adversely affect the subsequent processes. Therefore, in the embodiments of the present invention, the etching process 109 is a non-Ar atmosphere etching process too. However, in some embodiments of the present invention, an inert gas He may still be added into the atmosphere of the etching process 109 in order to remove the carbon-fluoride polymer more efficiently.

Subsequently, a dielectric gap filling process is conducted, wherein a metal deposition, electroplate or other suitable technology may be applied to fill a metal material 110 into the trench 108. In some embodiments of the present invention, the metal material 110 may be Al or Cu. In the present invention, a seed deposition is conducted to form a Cu seeding layer 111 on the sidewalls of the trench 108 and the portion of the conductive layer 103 exposed from the trench 108 preceding the metal material filling steps.

After some suitable back end processes are conducted, the single damascene interconnect structure 100 as shown in FIG. 1E is completed. In comparison the single damascene interconnect structure 100 with that provided by the prior arts, the single damascene interconnect structure 100 has a flared trench opening 107 which is contributive to the subsequent dielectric gap filling process, thus the single damascene interconnect structure 100 can provide higher dimensional accuracy and reliability than that of the prior arts with the same requisite feature dimension.

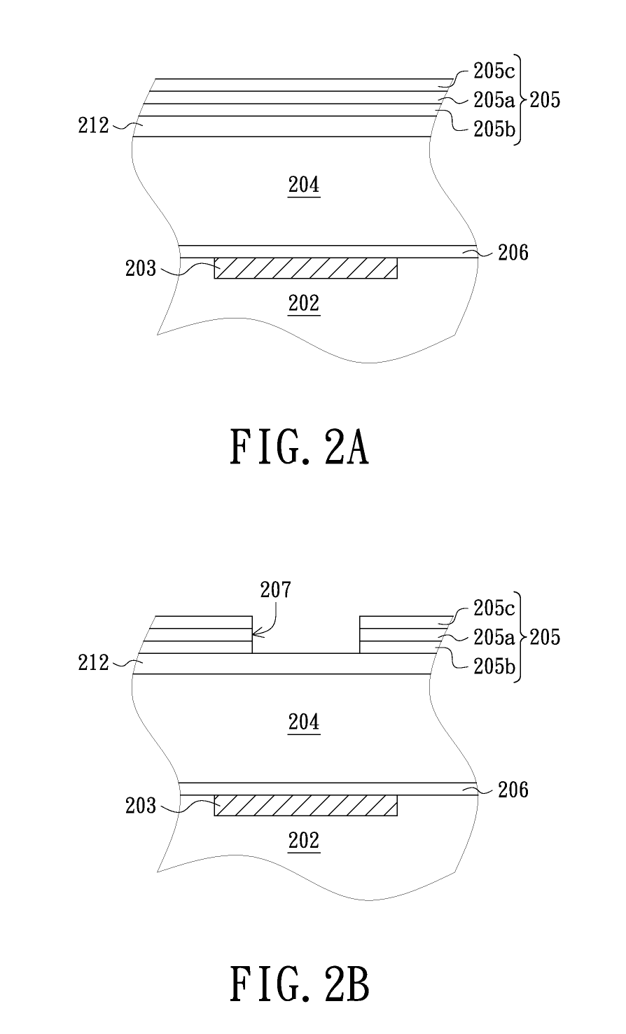

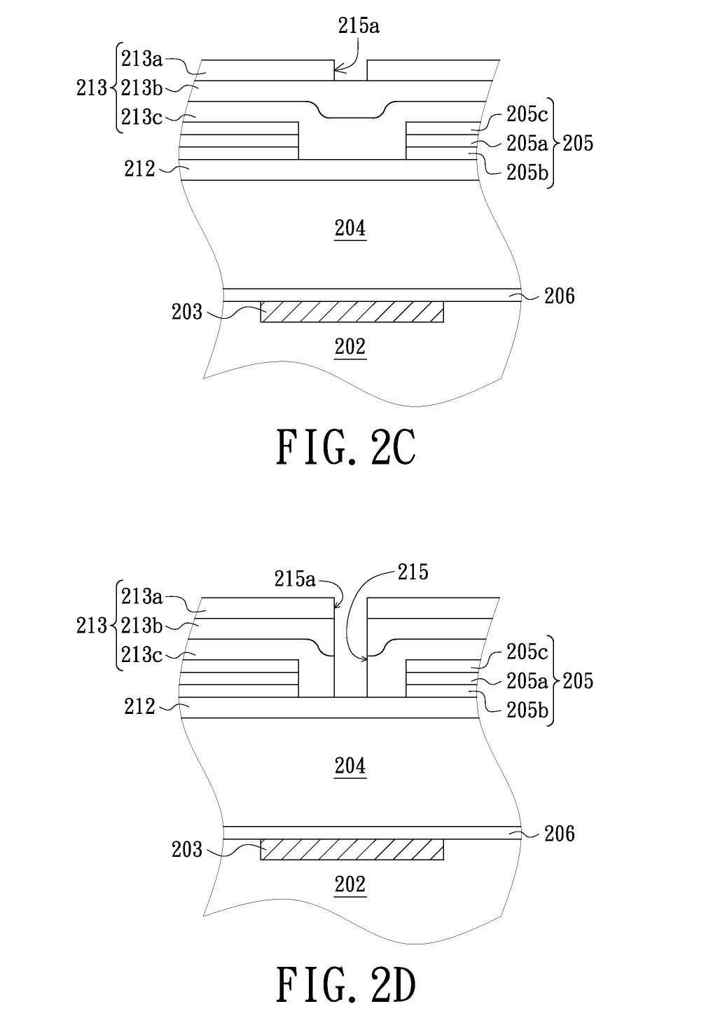

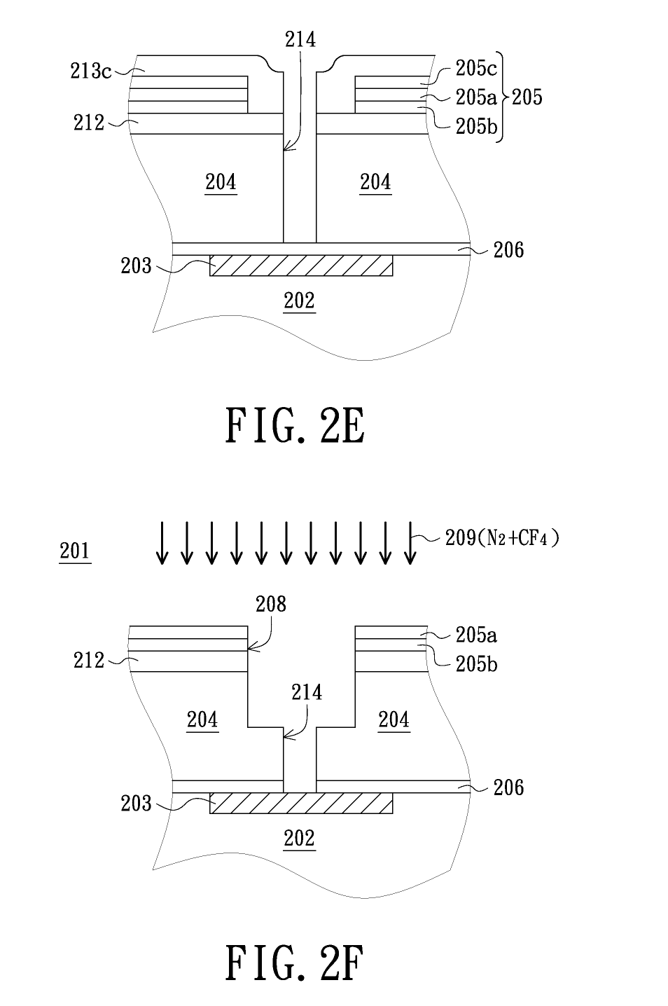

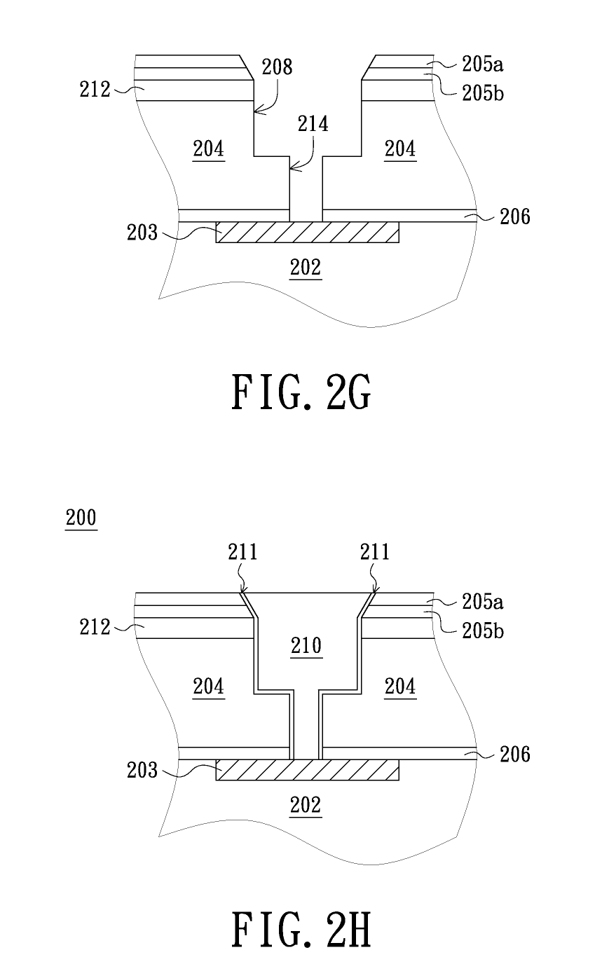

FIGS. 2A to 2H illustrate cross sectional views of a series processing structures for fabricating a dual damascene interconnect structure 200 in accordance with one embodiment of the present invention. The method for fabricating the dual damascene interconnect structure 200 comprises steps as follows:

A substrate 202 shown as the FIG. 2A is first provided, and then a conductive layer 203, an ILD 204, a buffer layer 212 and a hard mask layer 205 are formed in sequence over the substrate 202. Wherein the substrate 202 preferably is a silicon substrate; the conductive layer 203 may be a metal layer; the buffer layer 212 preferably is a silicon oxynitride (SiON) layer; the ILD 204 is preferably made of low resistance materials (k≦2.9), such as FSG, OSG or other ULK materials; and the hard mask layer 205 comprises a TiN layer 205a, a Ti layer 205b disposed beneath the TiN layer 205a and an silicon oxide capping layer 205c disposed on the TiN layer 205a. In some preferred embodiments, there is a bottom layer 206 consisting of SiN or SiCN formed between the conductive layer 203 and the ILD 204.

Next, the hard mask layer 205 is patterned to form at least one trench opening 207 exposing a portion of the buffer layer 212 (shown in FIG. 2B). Subsequently, a photo-resist layer 213 is formed on the patterned hard mask 205 so as to fill the trench opening 207, and the photo-resist layer 213 is then patterned to form a via opening 215 aligning to the trench opening 207.

In some embodiments of the present invention, the photo-resist layer 213 is a tri-layer photo-resist structure comprising an ArF photo-resist 213a, a SHB photo-resist 213b and an I-line photo-resist 213c stacked in sequence (Shown in FIG. 2C). In the present embodiment, the photo-resist layer 213 patterning comprises a pattern transfer procedure: At least one photo-resist opening 215a is firstly formed on the ArF photo-resist 213a by a suitable lithography process, and then at least one dry etching step is conducted to transfer the pattern defined by the at least one photo-resist opening 215a onto the SHB photo-resist 213b and the I-line photo-resist 213c so as to form the via opening 215.

In the present embodiment of the present invention, the pattern transfer procedure comprises two etching steps, for example, the SHB photo-resist 213b is etched in a CF₄ and trifluoromethane (CHF₃) atmosphere, the I-line photo-resist 213c is etched in a carbon dioxide (CO₂) and carbon monoxide (CO), thereby a portion of the buffer layer 212 is exposed from the transferred photo-resist opening 215 (shown in FIG. 2D).

Subsequently, a via-etching process using the patterned photo-resist layer 213 (e.g. the SHB photo-resist 213b and the I-line photo-resist 213c) serves as an etching mask is conducted to form a via 214 exposing the bottom layer 206 (shown in FIG. 2E). In some embodiments of the present invention, the via-etching process comprises at least two dry etching steps. For example, in the present embodiment, a first dry etching step operated in a CF₄ and octa-fluorocyclobutane (C₄F₈) atmosphere is conducted to remove a portion the buffer layer 212 and the ILD 204, and a second dry etching step operated in a C₄F₈ atmosphere is then conducted to remove the other portion the ILD 204, whereby the bottom layer 206 is exposed from the via 214.

Thereafter, a trench etching process using the patterned hard mask 205 serves as an etching mask is conducted to form a trench 208 passing through the bottom layer 206 and exposing the conductive layer 203. In some embodiments of the present invention, prior the trench etching process an photo-resist ashing process may be conducted to remove the patterned photo-resist layer 213 in a CO₂ atmosphere; and the trench etching process is then conducted in a CF₄ and C₄F₈ atmosphere to remove the portion of the bottom layer 206 exposed from the via 214 and the portions of the buffer layer 212 and the ILD 204 exposed from the trench opening 207 during the trench etching process, whereby a semiconductor structure 201 with a stepped trench is formed (shown in FIG. 2F). In the present embodiment, the silicon oxide capping layer 205c is also removed by the trench etching process while the portions of the buffer layer 212 and the ILD 204 are removed.

However, it should be appreciated that the bottom layer 206 may not be etched through by the trench etching process. Rather, in some embodiments of the present invention, the bottom layer 206 may be etched through by a subsequent etching process 209, thus the conductive layer 203 is exposed from the via 214 after the etching process 209 is conducted.

In the embodiments of the present invention, the etching process 209 is a dry etching process having an etching atmosphere essentially consisting of N₂ and CₓF_{y} used to partially remove a portion of the patterned hard mask 205 disposed over the sidewalls of the trench 208, such that the width of the trench opening 207 can be enlarged.

Typically, the aforementioned trench etching process may generate carbon-fluoride polymer residue remaining on the surface of the patterned hard mask 205 and the sidewalls of the trench 208, which may obstruct the subsequent process. The N₂ gas of the etching process 209 can react with and take away the carbon-fluoride polymer remained on the surface of the TiN layer 205a so as to enhance the etching process 209 pulling back the TiN layer 205a from the sidewalls of the trench 208 and to round the corner of the trench opening 207. Thereby, the portion of the patterned hard mask 205 disposed over the sidewalls of the trench 208 used to define the trench opening 207 may flare out, and the width of the trench opening 207 is enlarged (shown in FIG. 1D). In addition, the carbon-fluoride polymer may be removed more quickly, when the partial pressure of the N₂ atmosphere is increased; and the width of the trench opening 207 can be further enlarged if the thickness of the patterned hard mask 205 is shrinking. In the present embodiment, the etching process 209 is a plasma-based etching process with the atmosphere essentially consisting of N₂ and CF₄.

It should be noted that, although an etching process with O₂ atmosphere can also be used to remove the carbon-fluoride polymer, the etching process 209 is a non-O₂ atmosphere etching process. It is because that the O₂ atmosphere etching process has a similar selectivity for removing the TiN layer 205a and the ILD 204, thus it is difficult to control the etching depth. Therefore, if the etching process 209 imposes O₂ gas, the conductive layer 203 may be damaged by the O₂ gas due to an over-etching.

Besides, in order to remove the carbon-fluoride polymer remained on the sidewalls of the trench 208; an inert gas, such as Ar gas, is typically introduced into the O₂ atmosphere during the etching process 209. However, the O₂ atmosphere mixed with Ar gas may cause a sidewall etching by which a portion of the ILD 204 exposed from the trench 208 can be removed, so as to make the trench 208 shapes as a bowling or a kink and adversely affect the subsequent processes. Therefore, in the embodiments of the present invention, the etching process 209 is a non-Ar atmosphere etching process too. However, in some embodiments of the present invention, the inert gas He may still be added into the atmosphere of the etching process 209 in order to remove the carbon-fluoride polymer more efficiently.

Subsequently, a dielectric gap filling process is conducted, wherein a metal deposition, electroplate or other suitable technology is applied to fill a metal material 210 into the trench 208. In some embodiments of the present invention, the metal material 210 may be Al or Cu. In the present invention, a seed deposition is conducted to form a Cu seeding layer 211 on the sidewalls of the trench 208 and the and the portion of the conductive layer 203 exposed from the via 214 preceding the metal material filling steps.

After some suitable back end processes are conducted, the dual damascene interconnect structure 200 as shown in FIG. 2H is completed. In comparison the dual damascene interconnect structure 200 with that provided by the prior arts, the present dual damascene interconnect structure 200 has a flared trench opening 207 which is contributive to the subsequent dielectric gap filling process, thus the dual damascene interconnect structure 200 can provide higher dimensional accuracy and reliability than that of the prior art with the same requisite feature dimension.

In accordance with the aforementioned embodiments of the present invention, a method for forming a damascene trench structure in a semiconductor structure is provided, wherein the semiconductor structure comprises an ILD and a patterned hard mask stack in sequence. After a trench extending from the patterned hard mask downwards into the ILD is formed in the semiconductor structure, an etching process having an etching atmosphere essentially consisting of N₂ and CₓF_{y} is conducted to pull back the patterned hard mask disposed on the trench. Thereby, the width of the trench opening can be enlarged so as to enable the subsequent dielectric gap filling process be conducted successfully. Therefore, the drawbacks and problems encountered from the prior art can be solved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for fabricating a damascene trench structure comprising:
providing a semiconductor structure having an inner layer dielectric (ILD) and a patterned hard mask stacked in sequence, in which a trench extends from the patterned hard mask downwards into the ILD; and
etching the patterned hard mask in an atmosphere essentially consisting of nitrogen (N2) and carbon-fluoride compositions (CxFy).

2. The method according to claim 1, wherein the atmosphere is a non-oxygen (O₂) atmosphere.

3. The method according to claim 1, wherein the atmosphere is a non-argon (Ar) atmosphere.

4. The method according to claim 1, wherein the atmosphere essentially consists of nitrogen (N₂) and carbonteraflouride (CF₄).

5. The method according to claim 1, wherein the atmosphere further comprises helium (He).

6. The method according to claim 1, wherein the step for providing the semiconductor structure further comprises:
providing a substrate;
forming a conducted layer on the substrate;
forming a bottom layer on the conductive layer;
forming the ILD on the bottom layer;
forming a buffer layer on the ILD; and
forming the patterned hard mask on the buffer layer to make the patterned hard mask having a trench opening exposing a portion of the buffer layer.

7. The method according to claim 6, wherein the step for providing the semiconductor structure further comprises:
forming a photo-resist layer on the patterned hard mask so as to fill the trench opening;
patterning the photo-resist layer to form a via opening aligning to the trench opening and exposing a portion of the buffer layer;
conducting a via etching process using the patterned photo-resist layer serves as an etching mask to form a via exposing a portion of the bottom layer; and
conducting a trench etching process using the patterned hard mask serves as an etching mask to form the trench passing through the bottom layer and exposing a portion of the conductive layer.

8. The method according to claim 7, wherein the photo-resist layer is a tri-layer photo-resist.

9. The method according to claim 7, wherein the photo-resist layer patterning comprises a pattern transferring procedure.

10. The method according to claim 7, wherein the formation of the patterned hard mask comprises:
forming a titanium (Ti) layer on the buffer layer;
forming a titanium nitride (TiN) layer on the Ti layer; and
forming a capping layer on the TiN layer.

11. The method according to claim 7, wherein the trench etching process comprises:
conducting a first etching step for removing a portion of the buffer layer; and
conducting a second etching step for removing a portion of the ILD and exposing the conductive layer.

12. A method for fabricating a damascene interconnect structure comprising:
providing a semiconductor structure having an ILD and a patterned hard mask stacked in sequence, in which a trench extends from the patterned hard mask downwards into the ILD;
etching the patterned hard mask in an atmosphere essentially consisting of N₂ and CₓF_{y}; and
filling a metal material into the trench in connection with the conductive layer exposed from the trench.

13. The method according to claim 12, wherein the metal material filling steps further comprises a seed deposition to form a metal seeding layer on sidewalls of the trench.
